(19) United States
(12) Patent Application Publication
(10) Pub. No.: US 2026/0066853 A1
(43) Pub. Date: Mar. 5, 2026

(54) HIGH FREQUENCY MODULE AND COMMUNICATION DEVICE

(71) Applicant: Murata Manufacturing Co., Ltd., Nagaokakyo-shi (JP)

(72) Inventor: Kouta IWASA, Nagaokakyo-shi (JP)

(21) Appl. No.: 19/289,608

(22) Filed: Aug. 4, 2025

(30) Foreign Application Priority Data
Aug. 28, 2024 (JP) 2024-146803

(51) Int. Cl. H03F 3/00; H03F 3/24

(52) U.S. Cl. CPC H03F 3/00; H03F 3/245; H03F 2200/387; H03F 2200/451

(57) ABSTRACT

A high frequency module includes an amplifier circuit, a matching circuit, and a harmonic wave endpoint circuit. The amplifier circuit has an output terminal. The matching circuit is connected to the output terminal of the amplifier circuit, and includes a first inductor. The harmonic wave endpoint circuit connects the output terminal of the amplifier circuit and ground together, and includes a second inductor. The first inductor and the second inductor are arranged so that a magnetic field occurring at the first inductor and a magnetic field occurring at the second inductor are differentially coupled.

### CROSS REFERENCE TO RELATED APPLICATION

This application claims priority from Japanese Patent Application No. 2024-146803, filed on Aug. 28, 2024. The content of this application is incorporated herein by reference in its entirety.

### BACKGROUND OF THE DISCLOSURE

### 1. Field of the Disclosure

The present disclosure relates to a high frequency module and a communication device and, in particular, relates to a high frequency module including an amplifier circuit and a communication device including the high frequency module.

### 2. Description of the Related Art

Japanese Unexamined Utility Model Registration Application Publication No. 6-66127 discloses a high frequency power amplifier circuit. The high frequency power amplifier circuit of Japanese Unexamined Utility Model Registration Application Publication No. 6-66127 includes an FET as an amplifier circuit, an output matching circuit, and a series resonant circuit (harmonic wave endpoint circuit) including an inductance element (inductor). The series resonant circuit is high frequency removal means for removing high frequencies occurring at the FET.

### BRIEF SUMMARY OF THE DISCLOSURE

However, a parasitic inductor may occur on a wire connecting the output terminal of the FET and the series resonant circuit. For this reason, the parasitic inductor may affect the frequency characteristics of the series resonant circuit to prevent harmonic waves from being sufficiently removed, thereby degrading amplification efficiency of the amplifier circuit.

A possible benefit of the present disclosure is to provide a high frequency module and a communication device capable of improving amplification efficiency of the amplifier circuit.

A high frequency module according to an aspect of the present disclosure includes an amplifier circuit, a matching circuit, and a harmonic wave endpoint circuit. The amplifier circuit has an output terminal. The matching circuit is connected to the output terminal of the amplifier circuit and includes a first inductor. The harmonic wave endpoint circuit connects the output terminal of the amplifier circuit and ground together and includes a second inductor. The first inductor and the second inductor are arranged so that a magnetic field occurring at the first inductor and a magnetic field occurring at the second inductor are differentially coupled.

A communication device according to an aspect of the present disclosure includes the above-described high frequency module, and a signal processing circuit connected to the high frequency module.

According to the high frequency module and the communication device of an aspect of the present disclosure, amplification efficiency of the amplifier circuit can be improved.

### BRIEF DESCRIPTION OF THE SEVERAL VIEWS OF THE DRAWINGS

FIG. 1 is a circuitry diagram of main portions of a high frequency module according to a first embodiment;

FIG. 2 is a plan view of the high frequency module according to the first embodiment;

FIG. 3 is an equivalent circuit diagram of main portions of the high frequency module according to the first embodiment;

FIG. 4 is a circuitry configuration diagram of a communication device including the high frequency module according to the first embodiment;

FIG. 5 is a circuitry diagram of main portions of a high frequency module according to a second embodiment; and

FIG. 6 is an equivalent circuit diagram of main portions of the high frequency module according to the second embodiment.

### DETAILED DESCRIPTION OF THE DISCLOSURE

In the following, high frequency modules and communication devices according to embodiments are described by using the drawings. Any of the drawings to be referred to in the following embodiments is a schematic drawing, and a ratio of the size and thickness of each component in the drawings does not necessarily reflect an actual dimensional ratio.

### First Embodiment

### 1. Circuity Configuration of High Frequency Module

In the following, the circuit configuration of a high frequency module 1 according to a first embodiment is described with reference to the drawings.

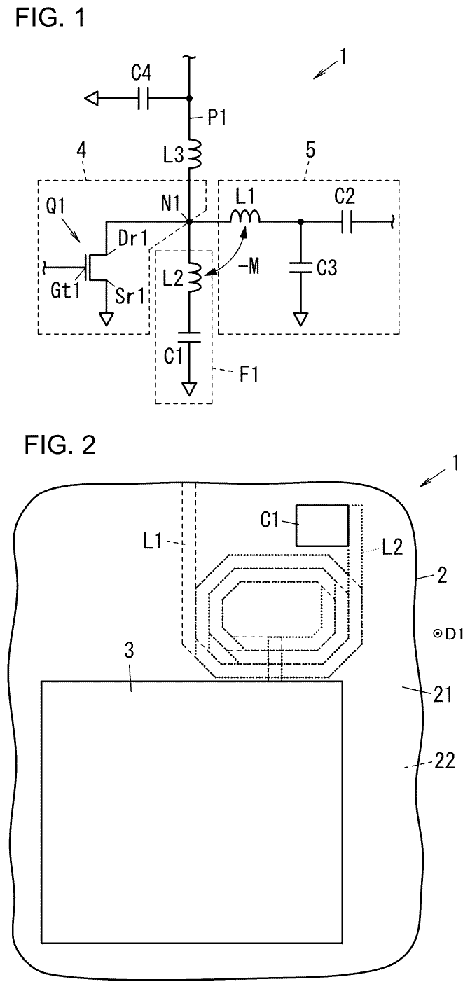

The high frequency module 1 includes an amplifier circuit 4, a power supply circuit P1, a harmonic wave endpoint circuit F1, and a matching circuit 5, as depicted in FIG. 1.

The amplifier circuit 4 is included in, for example, a power amplifier 151 (refer to FIG. 4) for power-amplifying a high frequency signal, and includes a transistor Q1. The transistor Q1 is, for example, a field effect transistor (FET). A gate electrode Gt1 of the transistor Q1 is connected to an input terminal of the power amplifier 151. A drain electrode Dr1 of the transistor Q1 is connected via an output terminal N1 of the amplifier circuit 4 to the power supply circuit P1, the harmonic wave endpoint circuit F1, and the matching circuit 5. A source electrode Sr1 of the transistor Q1 is connected to the ground.

The matching circuit 5 is a circuit for matching impedance between the output terminal N1 of the amplifier circuit 4 and an input terminal of a circuit (in FIG. 4, transmission filter 131) connected via the matching circuit 5 to the amplifier circuit 4. The matching circuit 5 is a matching circuit 141 of FIG. 4. The matching circuit 5 includes a first inductor L1 and capacitors C2 and C3.

The harmonic wave endpoint circuit F1 is a circuit for removing harmonic waves occurring at the amplifier circuit 4. The harmonic wave endpoint circuit F1 has a first end connected to the output terminal N1 of the amplifier circuit 4 and a second end connected to the ground. The harmonic wave endpoint circuit F1 includes a second inductor L2 and a capacitor C1. The harmonic wave endpoint circuit F1 connects the output terminal N1 of the amplifier circuit 4 and the ground together. In the harmonic wave endpoint circuit F1, for example, its impedance is set so that a short circuit occurs for even-order harmonic waves and an open circuit occurs for odd-order harmonic waves. In the harmonic wave endpoint circuit F1, the second inductor L2 and the capacitor C1 are connected in series. More specifically, in the harmonic wave endpoint circuit F1, the inductance of the second inductor L2 and the capacitance of the capacitor C1 are set so that a short circuit occurs for second-order harmonic waves. That is, the harmonic wave endpoint circuit F1 is a second-order harmonic wave endpoint circuit for reducing second-order harmonic waves to be outputted from the output terminal N1 of the amplifier circuit 4.

The power supply circuit P1 includes a path for supplying a drive voltage or drive current to the amplifier circuit 4. The power supply circuit P1 has a first end connected to the output terminal N1 of the amplifier circuit 4, the harmonic wave endpoint circuit F1, and the matching circuit 5 and a second end connected to a direct-current power supply (not depicted). The power supply circuit P1 includes a third inductor L3 and a capacitor C4. The third inductor L3 functions as a choke coil for reducing high-frequency noise flowing via the power supply circuit P1 into the drain electrode Dr1 of the transistor Q1.

### 2. Structure and Equivalent Circuit of High Frequency Module

The high frequency module 1 includes a mounting substrate 2, an electronic component 3, the first inductor L1, the second inductor L2, and the capacitor C1, as depicted in FIG. 2.

### 2.1 Mounting Substrate

The mounting substrate 2 has a principal surface 21 and a principal surface 22, as depicted in FIG. 2. The principal surface 21 and the principal surface 22 are opposed to each other in a thickness direction D1 of the mounting substrate 2.

The electronic component 3 and the capacitor C1 are arranged on the principal surface 21 of the mounting substrate 2. More specifically, the electronic component 3 and the capacitor C1 are mounted on the principal surface 21 of the mounting substrate 2.

In the mounting substrate 2, the first inductor L1 and the second inductor L2 are provided inside. “The first inductor L1 and the second inductor L2 are provided inside the mounting substrate 2” means that conductors configuring the first inductor L1 and the second inductor L2 are arranged between the principal surface 21 and the principal surface 22 in the thickness direction D1 of the mounting substrate 2. Note that part of the conductors configuring the first inductor L1 and the second inductor L2 may be formed on the principal surface 21 or the principal surface 22.

The mounting substrate 2 is, for example, a multilayer substrate including a plurality of dielectric layers (not depicted) and a plurality of conductive layers (not depicted). The plurality of dielectric layers and the plurality of conductive layers are stacked in the thickness direction D1. The plurality of conductive layers is formed in a predetermined pattern defined by each layer. The plurality of conductive layers each includes one or more conductive portions on one plane orthogonal to the direction D1. The material of each conductive layer is, for example, copper. The plurality of conductive layers includes a ground electrode to which a ground potential is supplied. In the high frequency module 1, a plurality of ground terminals (not depicted) and the ground electrode (not depicted) are electrically connected via a via conductor of the mounting substrate 2 and so forth. The mounting substrate 2 is, for example, a low temperature co-fired ceramics (LTCC) substrate. The mounting substrate 2 is not limited to a LTCC substrate but may be, for example, a resin multilayer substrate, printed wiring board, or high temperature co-fired ceramics (HTCC) substrate.

### 2.2 Electronic Component

The electronic component 3 is arranged on the principal surface 21 of the mounting substrate 2. The electronic component 3 is an IC chip including the amplifier circuit 4. The electronic component 3 is, for example, flip-chip mounted on the principal surface 21 of the mounting substrate 2.

### 2.3 Inductors

The first inductor L1 and the second inductor L2 are arranged in the mounting substrate 2. More specifically, the first inductor L1 and the second inductor L2 are provided inside the mounting substrate 2. Here, the first inductor L1 and the second inductor L2 are arranged on different layers in the mounting substrate 2. Note that the first inductor L1 and the second inductor L2 may be arranged on an IC chip configuring the electronic component 3. That is, the amplifier circuit 4, the first inductor L1, and the second inductor L2 may be arranged on the electronic component 3.

The first inductor L1 includes, for example, a plurality of conductors. The plurality of conductors is connected to one another so as to, for example, configure a spiral path. More specifically, the first inductor L1 includes a plurality of conductor patterns arranged in a polygonal shape (in FIG. 2, octagonal shape) in plan view from the thickness direction D1 and a plurality of conductor vias electrically connecting two conductor patterns.

The second inductor L2 includes, for example, a plurality of conductors. The plurality of conductors is connected to one another so as to, for example, configure a spiral path. More specifically, the second inductor L2 includes a plurality of conductor patterns arranged in a polygonal shape (in FIG. 2, octagonal shape) in plan view from the thickness direction D1 and a plurality of conductor vias electrically connecting two conductor patterns.

The first inductor L1 and the second inductor L2 are arranged, as in FIG. 1, so that a magnetic field occurring at the first inductor L1 and a magnetic field occurring at the second inductor L2 are differentially coupled. More specifically, the extending direction of the winding axis of the first inductor L1 and the extending direction of the winding axis of the second inductor L2 are both directed to the thickness direction D1 of the mounting substrate 2. Here, “the thickness direction of the mounting substrate 2” refers to a direction perpendicular to the principal surface 21 or the principal surface 22 of the mounting substrate 2.

Also, the first inductor L1 and the second inductor L2 overlap each other in plan view from the thickness direction D1 of the mounting substrate 2. Here, “the first inductor L1 and the second inductor L2 overlap each other in plan view from the thickness direction of the mounting substrate 2” means that, in plan view from the direction D1, at least part of an area where the conductors configuring the first inductor L1 are arranged overlaps at least part of an area where the conductors configuring the second inductor L2 are arranged.

Specifically, the first inductor L1 and the second inductor L2 are aligned in the direction D1. The first inductor L1 and the second inductor L2 are aligned between the principal surface 21 and the principal surface 22 of the mounting substrate 2 in the order of, for example, the first inductor L1 and then the second inductor L2. Note that the first inductor L1 and the second inductor L2 may be aligned between the principal surface 21 and the principal surface 22 of the mounting substrate 2 in the order of, for example, the second inductor L2 and then the first inductor L1. With this, as depicted in FIG. 1, the magnetic field occurring at the first inductor L1 and the magnetic field occurring at the second inductor L2 are coupled together to generate a mutual inductance.

Also, the first inductor L1 and the second inductor L2 are arranged so that the mutual inductance has a negative value. More specifically, in plan view from the extending direction of the winding axis of the first inductor L1, the winding direction of the first inductor L1 and the winding direction of the second inductor L2 are opposite to each other. That is, the rotating direction when the conductors configuring the first inductor L1 are traced from a first end on an amplifier circuit 4 side to a second end and the rotating direction when the conductors configuring the second inductor L2 are traced from a first end on an amplifier circuit 4 side to a second end are opposite to each other. With this, the orientation of the magnetic field occurring at the first inductor L1 from a current flowing through the first inductor L1 from the first end on the amplifier circuit 4 side to the second end and the orientation of the magnetic field occurring at the second inductor L2 from a current flowing through the second inductor L2 from the first end on the amplifier circuit 4 side to the second end on the ground side are both directed to the thickness direction of the mounting substrate and opposite to each other, and the first inductor L1 and the second inductor L2 are differentially coupled. For example, when a current flows from the output terminal N1 of the amplifier circuit 4 to the matching circuit 5 and the harmonic wave endpoint circuit F1, a magnetic field in a direction from the principal surface 21 toward the principal surface 22 of the mounting substrate 2 occurs inside the first inductor L1, and a magnetic field in a direction from the principal surface 22 toward the principal surface 21 of the mounting substrate 2 occurs inside the second inductor L2. Note that when a current flows from the output terminal N1 of the amplifier circuit 4 to the matching circuit 5 and the harmonic wave endpoint circuit F1, a magnetic field in a direction from the principal surface 22 toward the principal surface 21 of the mounting substrate 2 may occur inside the first inductor L1, and a magnetic field in a direction from the principal surface 21 toward the principal surface 22 of the mounting substrate 2 may occur inside the second inductor L2.

With this, in the high frequency module 1, the first inductor L1 and the second inductor L2 are differentially coupled. In FIG. 1, a negative mutual inductance between the first inductor L1 and the second inductor L2 is denoted as “−M”.

### 2.4 Capacitor

The capacitor C1 is arranged on the principal surface 21 of the mounting substrate 2. The capacitor C1 is, for example, a chip capacitor.

### 2.5 Equivalent Circuit

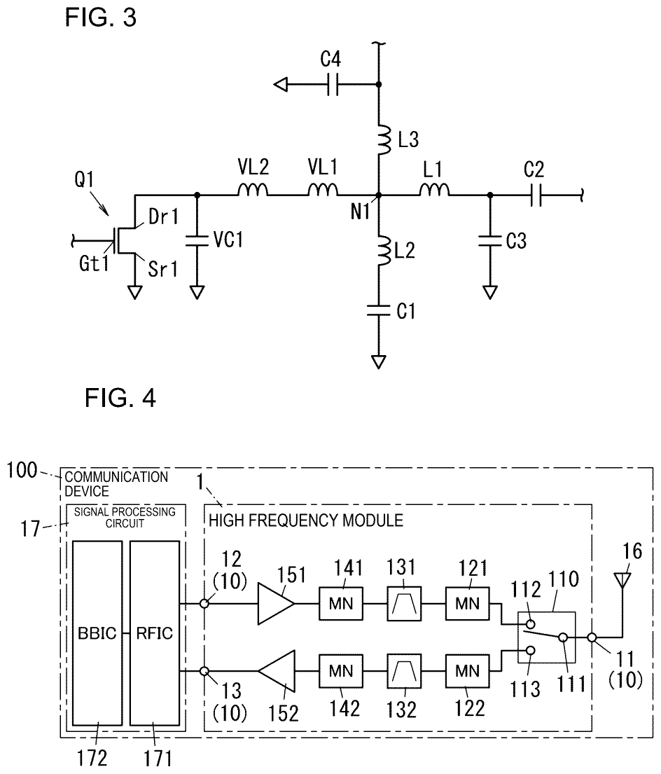

In an equivalent circuit of FIG. 3, a mutual inductance between the first inductor L1 and the second inductor L2 is indicated as an inductor VL1. Also, in the equivalent circuit of FIG. 3, a parasitic inductance occurring on a wire between the drain electrode Dr1 of the transistor Q1 and the output terminal N1 of the amplifier circuit 4 is indicated as an inductor VL2, and a parasitic capacitance thereon is indicated as a capacitor VC1.

As depicted in FIG. 3, the inductor VL1 and the inductor VL2 are connected in series on the wire between the drain electrode Dr1 of the transistor Q1 and the output terminal N1 of the amplifier circuit 4. That is, the inductance between the drain electrode Dr1 of the transistor Q1 and the ground has not only a contribution of the second inductor L2 of the harmonic wave endpoint circuit F1 but also a contribution of the inductor VL2 as a parasitic inductance and a contribution of the inductor VL1 as a mutual inductance. With this, the inductor VL1 and the inductor VL2 affect the frequency characteristics of the harmonic wave endpoint circuit F1. Specifically, since the impedance of the harmonic wave endpoint circuit F1 is not short-circuited for a second-order harmonic wave occurring at the transistor Q1, a voltage amplitude with a basic wave and a second-order harmonic wave being combined is outputted from the amplifier circuit 4. Thus, the voltage amplitude usable in a saturation region is decreased to degrade efficiency.

Here, in the high frequency module 1 of the first embodiment, the inductor VL1 has the negative mutual inductance-M. Therefore, an absolute value of a combined inductance of the inductor VL1 and the inductor VL2 is smaller than an absolute value of the inductance of the inductor VL2. Therefore, in the high frequency module 1 of the first embodiment, the value of the inductor VL2, which is an unwanted parasitic component, can be reduced, and it is therefore possible to bring the frequency characteristics of the harmonic wave endpoint circuit F1 closer to a design value. Thus, the second-order harmonic wave to be outputted is reduced, and the voltage amplitude can be efficiently used. Therefore, efficiency of the amplifier circuit 4 can be improved.

### 3. Other Configuration of High Frequency Module

The high frequency module 1 is used, for example, for a communication device 100, as depicted in FIG. 4. The communication device 100 is, for example, a mobile phone such as a smartphone. Note that the communication device 100 is not limited to a mobile phone and may be, for example, a wearable terminal such as a smartwatch, or the like. The high frequency module 1 is, for example, a high frequency module capable of supporting the 4th generation mobile communication (4G) standards, the 5th generation mobile communication (5G) standards, or the like. The 4G standards are, for example, Third Generation Partnership Project (3GPP, registered trademark) Long Term Evolution (LTE, registered trademark) standards. The 5G standards are, for example, 5G New Radio (NR). The high frequency module 1 can support, for example, carrier aggregation and dual connectivity.

The high frequency module 1 according to the first embodiment includes a plurality of external connection terminals 10, a switch 110, a matching circuit 121, a matching circuit 122, a transmission filter 131, a reception filter 132, the matching circuit 141, a matching circuit 142, the power amplifier 151, and a low noise amplifier 152, as depicted in FIG. 4. The plurality of external connection terminals 10 includes an antenna terminal 11, a signal input terminal 12, and a signal output terminal 13.

The power amplifier 151 is an amplifier for amplifying a transmission signal. The power amplifier 151 has an input terminal (not depicted) and an output terminal (not depicted). The input terminal of the power amplifier 151 is connected via the signal input terminal 12 to a signal processing circuit 17. The output terminal of the power amplifier 151 is connected via the matching circuit 141 to the transmission filter 131. The power amplifier 151 includes, as described above, the amplifier circuit 4.

The transmission filter 131 is a filter that lets a transmission signal pass therethrough. The transmission filter 131 is, for example, an acoustic wave filter including a plurality of series-arm resonators and a plurality of parallel-arm resonators. The acoustic wave filter is, for example, a surface acoustic wave (SAW) filter using a surface acoustic wave. The transmission filter 131 has an input terminal (not depicted) and an output terminal (not depicted). The input terminal of the transmission filter 131 is connected via the matching circuit 141 to the output terminal of the power amplifier 151. The output terminal of the transmission filter 131 is connected via the matching circuit 121 to the switch 110.

The low noise amplifier 152 is an amplifier for amplifying a reception signal. The low noise amplifier 152 has an input terminal (not depicted) and an output terminal (not depicted). The output terminal of the low noise amplifier 152 is connected via the signal output terminal 13 to the signal processing circuit 17. The input terminal of the low noise amplifier 152 is connected via the matching circuit 142 to the reception filter 132. The low noise amplifier 152 includes, for example, a transistor as a signal amplifier circuit.

The reception filter 132 is a filter that lets a reception signal pass therethrough. The reception filter 132 is, for example, an acoustic wave filter including a plurality of series-arm resonators and a plurality of parallel-arm resonators. The acoustic wave filter is, for example, a SAW filter using a surface acoustic wave. The reception filter 132 has an input terminal (not depicted) and an output terminal (not depicted). The input terminal of the reception filter 132 is connected via the matching circuit 122 to the switch 110. The output terminal of the reception filter 132 is connected via the matching circuit 142 to the output terminal of the low noise amplifier 152.

The switch 110 selects either of the transmission filter 131 and the reception filter 132 for connection to the antenna terminal 11. The switch 110 has a common terminal 111 and a plurality of (two in the depicted example) selection terminals 112 and 113. The common terminal 111 is connected to the antenna terminal 11. The selection terminal 112 is connected via the matching circuit 121 to the transmission filter 131. The selection terminal 113 is connected via the matching circuit 122 to the reception filter 132. The switch 110 includes, for example, a transistor as a switching element.

The matching circuit 121 is a circuit for taking impedance matching between the output terminal of the transmission filter 131 and the selection terminal 112 of the switch 110. The matching circuit 121 includes at least one of one or more capacitors and one or more inductors.

The matching circuit 122 is a circuit for taking impedance matching between the selection terminal 113 of the switch 110 and the input terminal of the reception filter 132. The matching circuit 122 includes at least one of one or more capacitors and one or more inductors.

The matching circuit 141 is a circuit for taking impedance matching between the output terminal of the power amplifier 151 and the input terminal of the transmission filter 131. The matching circuit 141 includes the above-described matching circuit 5.

The matching circuit 142 is a circuit for taking impedance matching between the output terminal of the reception filter 132 and the input terminal of the low noise amplifier 152. The matching circuit 142 includes at least one of one or more capacitors and one or more inductors.

### 4. Communication Device

The communication device 100 includes the high frequency module 1, the signal processing circuit 17, and an antenna 16, as depicted in FIG. 4.

The antenna 16 is connected to the antenna terminal 11 of the high frequency module 1. The antenna 16 has a transmitting function of emitting a transmission signal outputted from the high frequency module 1 as a radio wave and a receiving function of receiving a reception signal as a radio wave from outside and outputting the reception signal to the high frequency module 1.

The signal processing circuit 17 includes an RF signal processing circuit 171 and a baseband signal processing circuit 172. The signal processing circuit 17 processes a signal passing through the high frequency module 1. More specifically, the signal processing circuit 17 processes a transmission signal and a reception signal.

The RF signal processing circuit 171 is, for example, a radio frequency integrated circuit (RFIC). The RF signal processing circuit 171 performs signal processing on a high frequency signal.

The RF signal processing circuit 171 performs signal processing such as up-conversion and amplification on a transmission signal transmitted from the baseband signal processing circuit 172, and outputs the transmission signal subjected to the signal processing to the high frequency module 1. Also, the RF signal processing circuit 171 performs amplification and signal processing such as down-conversion on a reception signal outputted from the high frequency module 1, and outputs the reception signal subjected to the signal processing to the baseband signal processing circuit 172.

The baseband signal processing circuit 172 is, for example, a baseband integrated circuit (BBIC). The baseband signal processing circuit 172 performs predetermined signal processing on a transmission signal coming outside the signal processing circuit 17. A reception signal processed at the baseband signal processing circuit 172 is used as, for example, an image signal for image display or an audio signal for conversation.

Furthermore, the RF signal processing circuit 171 also has a function as a control unit that controls the connection of the switch 110 included in the high frequency module 1 based on transmission and reception of a high frequency signal (transmission signal, reception signal). Specifically, the RF signal processing circuit 171 switches the connection of the switch 110 of the high frequency module 1 with a control signal (not depicted). Note that the control unit may be provided outside the RF signal processing circuit 171 or may be provided to, for example, the high frequency module 1 or the baseband signal processing circuit 172.

### 5. Effects

The high frequency module 1 according to the first embodiment includes the amplifier circuit 4, the matching circuit 5, and the harmonic wave endpoint circuit F1. The amplifier circuit 4 has the output terminal N1. The matching circuit 5 is connected to the output terminal N1 of the amplifier circuit 4, and includes the first inductor L1. The harmonic wave endpoint circuit F1 connects the output terminal N1 of the amplifier circuit 4 and the ground together, and includes the second inductor L2. The first inductor L1 and the second inductor L2 are arranged so that a magnetic field occurring at the first inductor L1 and a magnetic field occurring at the second inductor L2 are differentially coupled. With this, in the high frequency module 1, amplification efficiency of the amplifier circuit 4 can be improved.

Also, in the high frequency module 1 according to the first embodiment, the harmonic wave endpoint circuit F1 is a second-order harmonic wave endpoint circuit for reducing second-order harmonic waves outputted from the amplifier circuit 4. With this, in the high frequency module 1, the second-order harmonic waves to be outputted are reduced, and the voltage amplitude can be efficiently used. Therefore, efficiency of the amplifier circuit 4 can be improved.

Furthermore, in the high frequency module 1 according to the first embodiment, the extending direction of the winding axis of the first inductor L1 and the extending direction of the winding axis of the second inductor L2 are identical to each other, that is, the thickness direction D1 of the mounting substrate 2. The first inductor L1 and the second inductor L2 overlap each other in plan view from the extending direction of the winding axis of the first inductor L1. With this, the magnetic field occurring at the first inductor L1 and the magnetic field occurring at the second inductor L2 are coupled together to generate a mutual inductance.

Still further, the high frequency module 1 according to the first embodiment includes the electronic component 3 and the mounting substrate 2. The electronic component 3 includes the amplifier circuit 4. The mounting substrate 2 has the electronic component 3, the first inductor L1, and the second inductor L2 arranged. The extending direction of the winding axis of the first inductor L1 is directed to the thickness direction D1 of the mounting substrate 2. With this, the size of the high frequency module 1 can be easily reduced.

Still further, the high frequency module 1 according to the first embodiment includes the electronic component 3 and the mounting substrate 2. The electronic component 3 may have the amplifier circuit 4, the first inductor L1, and the second inductor L2 arranged. The mounting substrate 2 has the electronic component 3 arranged. The extending direction of the winding axis of the first inductor L1 is directed to the thickness direction D1 of the mounting substrate 2. Also, with this configuration, the size of the high frequency module 1 can be easily reduced.

Still further, the high frequency module 1 according to the first embodiment includes the power amplifier 151. The power amplifier 151 includes the amplifier circuit 4. With this, amplification efficiency of the transmission signal in the high frequency module 1 can be improved. Thus, the size of the power amplifier 151 can be reduced, and the size of the high frequency module 1 can be easily reduced.

Still further, the communication device 100 according to the first embodiment includes the high frequency module 1 and the signal processing circuit 17. The signal processing circuit 17 is connected to the high frequency module 1. With this, in the communication device 100, transmission and reception of a predetermined high frequency signal can be made.

### Second Embodiment

### 1. Configuration

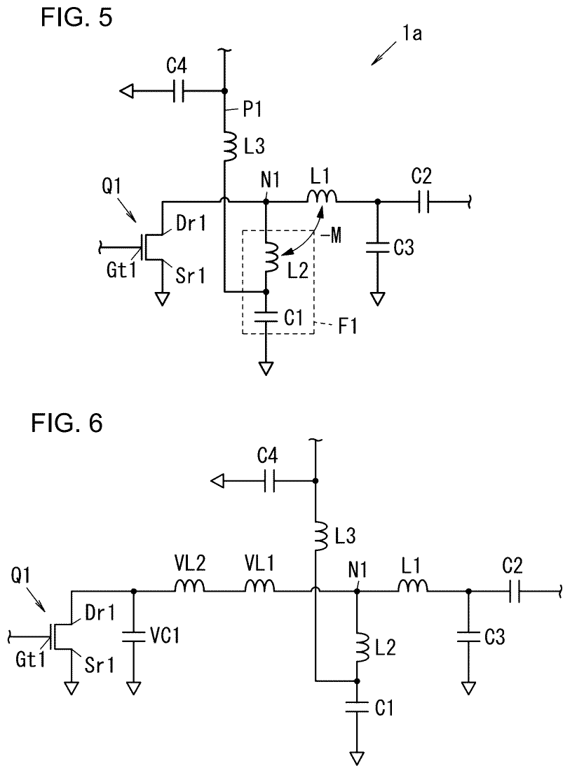

In a high frequency module 1a according to a second embodiment, as depicted in FIG. 5, the power supply circuit P1 is connected between the second inductor L2 and the capacitor C1. Here, the capacitor C1 is connected between the second inductor L2 and the ground in series to the second inductor L2 in the harmonic wave endpoint circuit F1.

Also, in the high frequency module 1a according to the second embodiment, the second inductor L2 and the first inductor L1 are negatively coupled. Therefore, as depicted in FIG. 6, which is an equivalent circuit diagram of the high frequency module 1a, a state is such that the inductor VL1 and the inductor VL2 are connected in series on a wire between the drain electrode Dr1 of the transistor Q1 of the power amplifier 151 and the output terminal N1 of the amplifier circuit 4. As described above, since the inductor VL1 and the inductor VL2 cancel each other out, the influence of the parasitic inductor VL1 on the frequency characteristics of the harmonic wave endpoint circuit F1 can be reduced.

Furthermore, in the high frequency module 1a according to the second embodiment, the power supply circuit P1 is connected between the second inductor L2 and the capacitor C1. With this, other than the third inductor L3, the inductor VL1, and the inductor VL2, the second inductor L2 is arranged between a direct-current power supply, which is the second end of the power supply circuit P1, and the drain electrode Dr1 of the transistor Q1 of the power amplifier 151. In the high frequency module 1a according to the second embodiment, that second inductor L2 functions as part of a choke inductor of the power supply circuit P1.

### 2. Effects

In the high frequency module 1a according to the second embodiment, the power supply circuit P1 of the amplifier circuit 4 is connected between the second inductor L2 and the capacitor C1. With this, the second inductor L2 functions as part of a choke inductor in the power supply circuit P1. Thus, the size of the high frequency module 1a can be easily reduced.

### Modifications

While the first inductor L1 and the second inductor L2 are incorporated in the mounting substrate 2 in the high frequency module 1, 1a according to the first and second embodiments, one or both of the first inductor L1 and the second inductor L2 may be chip inductors to be mounted on the mounting substrate 2. For example, the first inductor L1 may be a chip inductor, the extending direction of the winding axis of which is directed to the thickness direction D1 of the mounting substrate 2, and, in plan view from the direction D1, may be arranged so as to overlap the second inductor L2 incorporated in the mounting substrate 2. Also, for example, the first inductor L1 and the second inductor L2 may be chip inductors, the extending direction of the winding axis of which crosses the thickness direction D1 of the mounting substrate 2. In this case, the first inductor L1 and the second inductor L2 have the same extending direction of the winding axis and are arranged so that the first inductor L1 and the second inductor L2 overlap each other in plan view from the extending direction of the winding axis of the first inductor L1.

Also, while the power amplifier 151 includes the amplifier circuit 4 in the high frequency module 1, 1a according to the first and second embodiments, the low noise amplifier 152 may include the amplifier circuit 4. Also, in this case, amplification efficiency of a reception signal can be improved in the high frequency module 1, 1a.

Furthermore, in the transistor Q1 included in the amplifier circuit 4 in the first and second embodiments, the connection destination of each of the gate electrode Gt1, the drain electrode Dr1, and the source electrode Sr1 may be different from those in the embodiments as long as the transistor Q1 can function as a signal amplifying element.

Furthermore, the transistor Q1 included in the amplifier circuit 4 in the first and second embodiments may be a bipolar transistor. When the transistor Q1 is a bipolar transistor, for example, the base electrode of the transistor Q1 is connected to the input terminal of the amplifier circuit 4, the collector electrode thereof is connected to the output terminal N1 of the amplifier circuit 4, and the emitter electrode thereof is connected to the ground.

### Aspects

A high frequency module (1; 1a) according to a first aspect includes an amplifier circuit (4), a matching circuit (5), and a harmonic wave endpoint circuit (F1). The amplifier circuit (4) has an output terminal (N1). The matching circuit (5) is connected to the output terminal (N1) of the amplifier circuit (4), and includes a first inductor (L1). The harmonic wave endpoint circuit (F1) connects the output terminal (N1) of the amplifier circuit (4) and ground together, and includes a second inductor (L2). The first inductor (L1) and the second inductor (L2) are arranged so that a magnetic field occurring at the first inductor and a magnetic field occurring at the second inductor are differentially coupled.

According to the high frequency module (1; 1a) of the above-described aspect, amplification efficiency of the amplifier circuit (4) can be improved.

In the high frequency module (1; 1a) according to a second aspect, in the first aspect, the harmonic wave endpoint circuit (F1) is a second-order harmonic wave endpoint circuit for reducing second-order harmonic waves outputted from the amplifier circuit (4).

According to the high frequency module (1; 1a) of the above-described aspect, the second-order harmonic waves to be outputted from the amplifier circuit (4) together with the second-order harmonic waves are reduced, and voltage amplitude can be efficiently used. Therefore, efficiency of the amplifier circuit (4) can be improved.

In the high frequency module (1a) according to a third aspect, in the first or second aspect, the harmonic wave endpoint circuit (F1) further includes a capacitor (C1) connected in series between the second inductor (L2) and the ground. A power supply circuit (P1) of the amplifier circuit (4) is connected between the second inductor (L2) and the capacitor (C1).

According to the high frequency module (1a) of the above-described aspect, the second inductor (L2) functions as a choke inductor in the power supply circuit (P1). Thus, the size of the high frequency module (1a) can be easily reduced.

In the high frequency module (1; 1a) according to a fourth aspect, in any one of the first to third aspects, an extending direction of a winding axis of the first inductor (L1) and an extending direction of a winding axis of the second inductor (L2) are identical to each other. The first inductor (L1) and the second inductor (L2) overlap each other in plan view from the extending direction of the winding axis of the first inductor (L1).

According to the high frequency module (1; 1a) of the above-described aspect, the magnetic field occurring at the first inductor (L1) and the magnetic field occurring at the second inductor (L2) are coupled together to generate a mutual inductance.

The high frequency module (1; 1a) according to a fifth aspect further includes an electronic component (3) and a mounting substrate (2), in the fourth aspect. The electronic component (3) includes the amplifier circuit (4). The mounting substrate (2) has the electronic component (3), the first inductor (L1), and the second inductor (L2) arranged. The extending direction of the winding axis of the first inductor (L1) is directed to a thickness direction (D1) of the mounting substrate (2).

According to the high frequency module (1; 1a) of the above-described aspect, the size of the high frequency module (1; 1a) can be easily reduced.

The high frequency module (1; 1a) according to a sixth aspect further includes a mounting substrate (2), in the fourth aspect. The mounting substrate (2) has an electronic component (3) arranged. The electronic component (3) has the amplifier circuit (4), the first inductor (L1), and the second inductor (L2) arranged. The extending direction of the winding axis of the first inductor (L1) is directed to a thickness direction (D1) of the mounting substrate (2).

According to the high frequency module (1; 1a) of the above-described aspect, the size of the high frequency module (1; 1a) can be easily reduced.

The high frequency module (1; 1a) according to a seventh aspect further includes a power amplifier (151), in any one of the first to sixth aspects. The power amplifier (151) includes the amplifier circuit (4).

According to the high frequency module (1; 1a) of the above-described aspect, amplification efficiency of the transmission signal can be improved. Thus, the size of the power amplifier (151) can be reduced, and the size of the high frequency module (1) can be easily reduced.

A communication device (100) according to an eighth aspect includes the high frequency module (1; 1a) according to any one of the first to seventh aspects, and a signal processing circuit (17). The signal processing circuit (17) is connected to the high frequency module (1; 1a).

According to the communication device (100) of the above-described aspect, transmission and reception of a predetermined high frequency signal can be made.

What is claimed is:

1. A high frequency module comprising:
an amplifier circuit having an output terminal;
a matching circuit connected to the output terminal of the amplifier circuit, and comprising a first inductor; and
a harmonic wave endpoint circuit connecting the output terminal of the amplifier circuit to ground, and comprising a second inductor,
wherein the first inductor and the second inductor are arranged so that a magnetic field occurring at the first inductor and a magnetic field occurring at the second inductor are differentially coupled.

2. The high frequency module according to claim 1, wherein the harmonic wave endpoint circuit is a second-order harmonic wave endpoint circuit configured to reduce second-order harmonic waves outputted from the amplifier circuit.

3. The high frequency module according to claim 1,
wherein the harmonic wave endpoint circuit further comprises a capacitor connected in series between the second inductor and ground, and
wherein a power supply circuit of the amplifier circuit is connected between the second inductor and the capacitor.

4. The high frequency module according to claim 1,
wherein an extension direction of a winding axis of the first inductor and an extension direction of a winding axis of the second inductor are the same, and
wherein the first inductor and the second inductor overlap each other in a plan view along the extension direction of the winding axis of the first inductor.

5. The high frequency module according to claim 4, further comprising:
an electronic component comprising the amplifier circuit; and
a mounting substrate on which the electronic component, the first inductor, and the second inductor are arranged,
wherein the extension direction of the winding axis of the first inductor is a thickness direction of the mounting substrate.

6. The high frequency module according to claim 4, further comprising:
an electronic component comprising the amplifier circuit, the first inductor, and the second inductor; and
a mounting substrate on which the electronic component is arranged,
wherein the extension direction of the winding axis of the first inductor is a thickness direction of the mounting substrate.

7. The high frequency module according to claim 1, further comprising:
a power amplifier,
wherein the power amplifier comprises the amplifier circuit.

8. A communication device comprising:
the high frequency module according to claim 1; and
a signal processing circuit connected to the high frequency module.
